(19) United States
(12) Patent Application Publication
(10) Pub. No.: US 2013/0186460 A1
(43) Pub. Date: Jul. 25, 2013

(54) SOLAR CELL AND METHOD OF MANUFACTURING THE SAME

(71) Applicants: Miin-Jang Chen, Taipei City (TW); Hsin-Jui Chen, Taipei City (TW)

(72) Inventors: Miin-Jang Chen, Taipei City (TW); Hsin-Jui Chen, Taipei City (TW)

(73) Assignee: NATIONAL TAIWAN UNIVERSITY, Taipei (TW)

(21) Appl. No.: 13/553,816

(22) Filed: Jul. 20, 2012

(30) Foreign Application Priority Data
Jan. 20, 2012 (TW) 101102511

(51) Int. Cl. H01L 31/0236; H01L 31/18; B82Y 99/00

(52) U.S. Cl. 136/256; 438/98; 257/E31.11; 977/948

(57) ABSTRACT

A method of manufacturing a solar cell includes following steps. A first-conductive-type silicon wafer is provided. The silicon wafer has a first (front) surface and a second (back) surface facing each other, and a plurality of nanorods are located on the first surface. A doping process is performed, so that the conductive type of the nanorods and the conductive type of one portion of the silicon wafer located below the nanorods are changed to a second conductive type. A first electrode is formed on the second surface, and a first annealing process is performed on the first electrode. A second electrode is formed on a partial region of the first surface. An atomic layer deposition process is performed to form a passivation layer on the first surface and surfaces of the nanorods.

### CROSS-REFERENCE TO RELATED APPLICATION

This application claims the priority benefit of Taiwan application serial no. 101102511, filed on Jan. 20, 2012. The entirety of the above-mentioned patent application is hereby incorporated by reference herein and made a part of this specification.

### BACKGROUND OF THE INVENTION

1. Field of the Invention

The invention relates to a solar cell and a method of manufacturing the same. More particularly, the invention relates to a solar cell having a nanorod array structure on which a passivation layer is formed and a method of manufacturing the solar cell.

2. Description of Related Art

Due to global warming and impending energy crisis, scientific researches are now directed to renewable sources of energy. Specifically, solar cells have become one of the most popular renewable energy sources. The quality of a solar cell can be evaluated through photoelectric conversion efficiency which may be affected by a variety of factors, such as light absorption, minority carrier recombination, and so on. In order to ameliorate the efficiency of solar cells, various anti-reflection techniques have been proposed. For instance, a pyramid textured structure may be formed on a front surface of mono-crystalline silicon through anisotropic etching, such that incident light, after being reflectecd by the surface, may still have an opportunity to enter the solar cell. Therefore, the reflectance can be reduced. It has been also proposed that a silicon nitride thin film with certain thickness is deposited on the surface of the solar cell to form an anti-reflection coating layer for reducing the reflectance. Nonetheless, the effects achieved by applying the aforesaid anti-reflection techniques are deemed insufficient.

Alternatively, a surface etching process may be performed to form a nanorod array structure with a large aspect ratio on a silicon wafer. Low reflectivity can be accomplished within the wide spectral region even through no anti-reflection layer is formed in said structure. In this case, the silicon wafer appears to be black and is thus referred to as a black silicon wafer. FIG. 1 is a schematic view illustrating a solar cell formed by applying the black silicon wafer with the nanorod array structure. With reference to FIG. 1, the solar cell 10 includes a silicon wafer 12, a first electrode 18, and a second electrode 20. The silicon wafer 12 includes a p-type region 14 and an n-type region 16. The n-type region 16 includes a plurality of nanorods 16a and a portion of the silicon wafer 16b located below the nanorods 16a. The first electrode 18 and the second electrode 20 are respectively formed on two opposite sides of the silicon wafer 12. In the process of forming the nanorods 16a by etching the silicon wafer 12, however, a number of defects may be present on surfaces of the nanorods 16a. Hence, when electrons and holes are generated after the solar cell is illuminated, the electrons and holes likely recombine with each other at the surface defect states. As such, the photoelectric conversion efficiency of the solar cell is significantly reduced.

### SUMMARY OF THE INVENTION

The invention is directed to a method of manufacturing a solar cell. In the method, a passivation layer is formed on a silicon wafer with a nanorod array structure through performing an atomic layer deposition process.

The invention is further directed to a solar cell having a passivation layer for improving efficiency of the solar cell.

In the invention, a method of manufacturing a solar cell includes following steps. A first-conductive-type silicon wafer is provided. The silicon wafer has a first (front) surface and a second (back) surface facing each other, and a plurality of nanorods are located on the first surface. A doping process is performed, such that the conductive type of the nanorods and the conductive type of one portion of the silicon wafer located below the nanorods are changed to a second conductive type. A first electrode is formed on the second surface, and a first annealing process is performed on the first electrode. A second electrode is formed on a partial region of the first surface. An atomic layer deposition process is performed to form a passivation layer on the first surface and surfaces of the nanorods.

According to an embodiment of the invention, the passivation layer includes a film layer with low interfacial state density and a film layer with high fixed charge density, and the film with high fixed charge density is formed upon the film layer with the low interfacial state density.

According to an embodiment of the invention, a method of forming the passivation layer includes following steps. A first atomic layer deposition process is performed to form the film layer with low interfacial state density on the first surface and the surfaces of the nanorods. A second atomic layer deposition process is performed to form the film layer with high fixed charge density upon the film layer with low interfacial state density.

According to an embodiment of the invention, the method of manufacturing the solar cell further includes performing a second annealing process on the film layer with low interfacial state density after performing the first atomic layer deposition process and before the second atomic layer deposition process.

According to an embodiment of the invention, the method of manufacturing the solar cell further includes performing a second annealing process after performing the second atomic layer deposition process.

According to an embodiment of the invention, the method of manufacturing the solar cell further includes performing a second annealing process on the passivation layer after forming the passivation layer.

In the invention, a solar cell that includes a silicon wafer, a first electrode, a second electrode, and a passivation layer is provided. The silicon wafer has a first (front) surface and a second (back) surface facing each other. A plurality of nanorods are located on the first surface. Here, the conductive type of the nanorods and the conductive type of one portion of the silicon wafer located below the nanorods are first conductive types, and the conductive type of the other portion of the silicon wafer is a second conductive type. The first electrode is configured on the second surface. The second electrode is configured on a partial region of the first surface. The passivation layer is configured on the first surface and surfaces of the nanorods.

According to an embodiment of the invention, a material of the passivation layer includes Al₂O₃, MN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof.

According to an embodiment of the invention, the passivation layer includes a film layer with low interfacial state density and a film layer with high fixed charge density, and the film with high fixed charge density is configured upon the film layer with low interfacial state density.

According to an embodiment of the invention, a material of the film layer with low interfacial state density includes Al₂O₃, MN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof.

According to an embodiment of the invention, a material of the film layer with high fixed charge density includes Al₂O₃, AN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof.

According to an embodiment of the invention, a thickness of the passivation layer ranges from about 1 Å to about 1 μm.

Based on the above, the atomic layer deposition process is performed to form the surface passivation layer on the silicon wafer with the nanorod structure, as described in the invention. Thereby, interfacial state density may be reduced, and the carrier recombination rate may be lowered down. As a result, the efficiency of the solar cell may be effectively improved.

Other features and advantages of the invention will be further understood from the further technological features disclosed by the embodiments of the invention wherein there are shown and described embodiments of this invention, simply by way of illustration of modes best suited to carry out the invention.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view illustrating a conventional silicon solar cell with a nanorod array structure.

FIG. 2A to FIG. 2C are schematic cross-sectional views illustrating a process of manufacturing of a solar cell according to a first embodiment of the invention.

FIG. 3A and FIG. 3B are schematic cross-sectional views illustrating a process of manufacturing of a solar cell according to a second embodiment of the invention.

### DESCRIPTION OF EMBODIMENTS

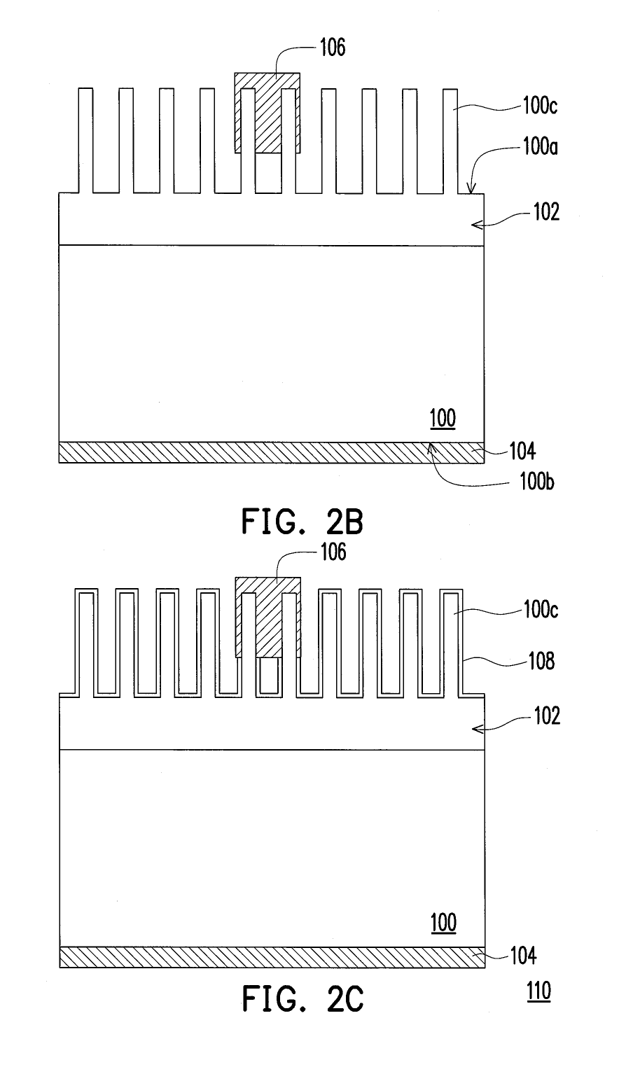

FIG. 2A to FIG. 2C are schematic cross-sectional views illustrating a process of manufacturing of a solar cell according to a first embodiment of the invention. With reference to FIG. 2A, a method of manufacturing a solar cell is provided in the first embodiment. In the method, a p-type silicon wafer 100 is exemplarily provided. The silicon wafer 100 has a first (front) surface 100a and a second (back) surface 100b facing each other, and a plurality of nanorods 100c are located on the first surface 100a. The nanorods 100c are formed by performing a surface etching process on the silicon wafer 100 with appropriate etchant, for instance. After the nanorods 100c are formed, a doping process is performed to incorporate n-type dopants into the nanorods 100c and one portion of the silicon wafer 100 located below the nanorods 100c, such that the conductive type of the nanorods 100c and the conductive type of the portion of the silicon wafer 100c located below the nanorods 100c are changed to n-type. Namely, an n-type region 102 is formed in the silicon wafer 100.

Said doping process is, for instance, a phosphorous doping process. In the phosphorous doping process, the silicon wafer 100 is coated with a phosphorus-containing spin-on dopant, and thermal treatment is conducted to diffuse phosphorous into the nanorods 100c and the portion of the silicon wafer 100 located below the nanorods 100c.

With reference to FIG. 2B, a first electrode 104 is formed on the second surface 100b. The first electrode 104 is formed by evaporation, for instance, and a material of the first electrode 104 may be aluminum, for instance. After the first electrode 104 is formed, an annealing process is performed on the first electrode 104. A p+ doped region (not shown) is formed in the silicon wafer 100 adjacent to the first electrode 104 during the annealing process. This results in a back surface field (BSF) effect and may significantly reduce the carrier recombination rate at the second surface 100b. A second electrode 106 is formed on a partial region of the first surface 100a. The second electrode 106 may be made of silver and formed by evaporation, for instance.

With reference to FIG. 2C, an atomic layer deposition (ALD) process is performed to form a passivation layer 108 on the first surface 100a and surfaces of the nanorods 100c. So far, the fabrication of the solar cell 110 is completed. A material of the passivation layer 108 may be any material that is capable of passivating a surface and is suitable for being formed by the ALD process, such as Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, Ge^{O}₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof. The properties of the passivation layer 108 may be changed by modifying parameters of the ALD process. For instance, a film layer with low interfacial state density may be formed, or a film layer with high fixed charge density may be formed.

In the first embodiment, the passivation layer 108 may be made of aluminum oxide, for instance, and a thickness of the passivation layer 108, for instance, ranges from about 1 Å to about 1 μm. Besides, the ALD process is performed in a single-pulse mode according to this embodiment, for instance. Namely, the ALD process consists of multiple identical ALD cycles, each of which contains the following sequence: one trimethyl aluminum (TMA) pulse→inert gas purge→one H₂O vapor pulse→inert gas purge. However, the invention is not limited thereto. According to other embodiments, the ALD process may also be performed in a multi-pulse mode. Namely, the ALD cycle contains the following sequence: multiple TMA pulses→inert gas purge→multiple H₂O vapor pulses→inert gas purge.

Besides, in another embodiment, after the passivation layer 108 is formed, an annealing process may be performed on the passivation layer 108, so as to further reduce the interfacial state density between the passivation layer 108 and the silicon wafer 100. Said annealing process is performed in the mixture of nitrogen and hydrogen, for instance.

According to the first embodiment, a material of the passivation layer 108 is, for example but not limited to, aluminum oxide with low interfacial state density. The passivation layer 108 covers the nanorods 100c and reduces the defect density on the surfaces of the nanorods 100c. As such, the carrier recombination rate can be suppressed, and the photoelectric conversion efficiency of the solar cell can be improved.

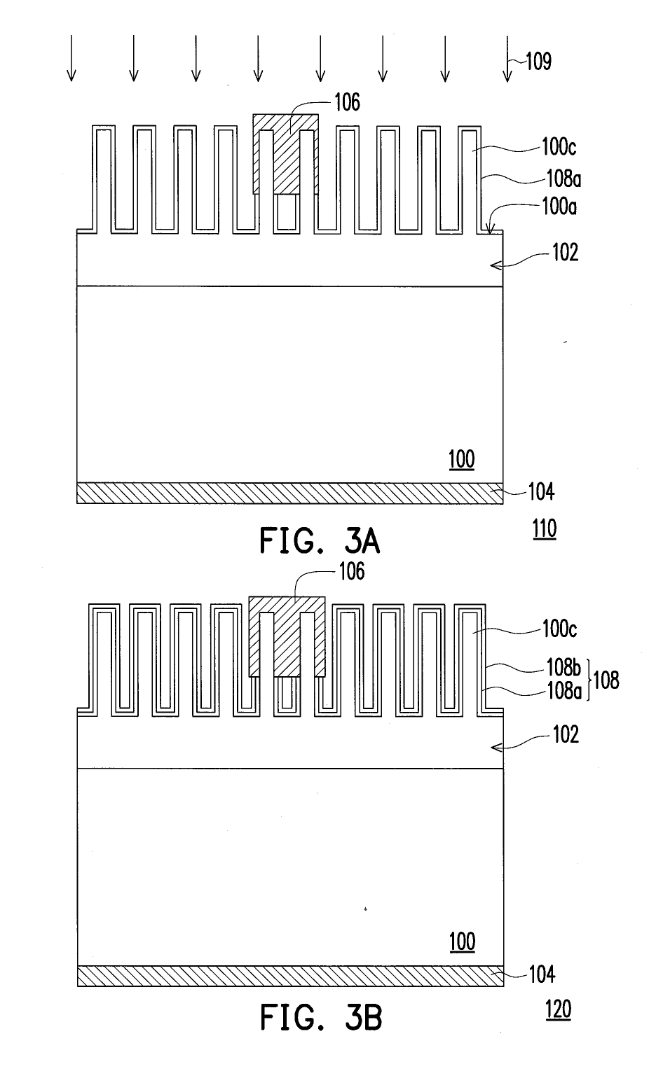

FIG. 3A and FIG. 3B are schematic cross-sectional views illustrating a process of manufacturing of a solar cell according to a second embodiment of the invention. Please refer to both FIG. 3A and FIG. 3B. The process of manufacturing the solar cell described in the second embodiment is similar to that described in the first embodiment. The difference therebetween lies in that the first ALD process is performed after the second electrode 106 is formed according to the second embodiment, so as to form a film layer 108a with low interfacial state density on the first surface 100a and the surfaces of the nanorods 100c. A material of the film layer 108a with low interfacial state density is aluminum oxide, for instance. An annealing process 109 is optionally performed on the film layer 108a with low interface state density. The annealing process 109 is performed in the mixture of nitrogen and hydrogen, for instance. A second ALD process is performed to form a film layer 108b with high fixed charge density upon the film layer 108a with low interface state density, so as to form the solar cell 120. A material of the film layer 108b with the high fixed charge density is zirconium oxide, for instance. In another embodiment, the annealing process 109 may be performed after the second ALD process, rather than between the first ALD process and the second ALD process.

According to the second embodiment, the passivation layer 108 includes the film layer 108a with low interfacial state density; hence, as described in the first embodiment, the carrier recombination rate may be suppressed. Besides, the passivation layer 108 includes the film layer 108b with high fixed charge density; thereby, minority carriers around the surfaces of the nanorods 100c may be repelled away from the interface. Thus the carrier recombination rate can be lowered down, such that photoelectric conversion efficiency of the solar cell 120 can be improved.

Experimental examples and a reference example are provided hereinafter to clarify the embodiments of the invention and the effects achieved herein.

### Reference Example

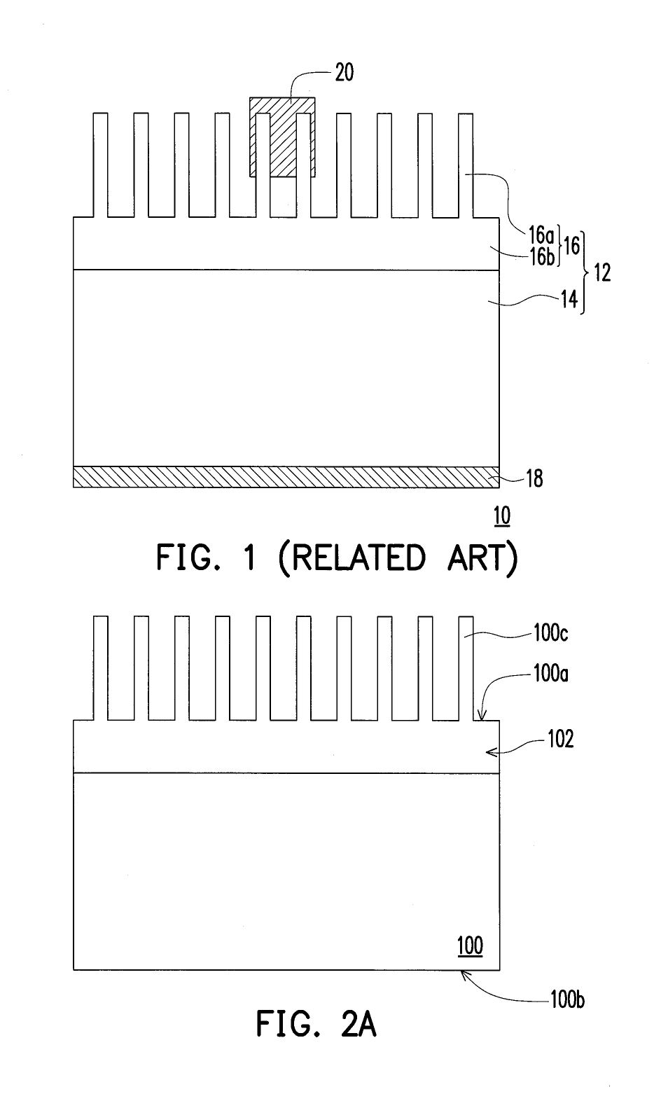

In the reference example, a conventional silicon solar cell with a nanorod array structure is provided. The structure of the silicon solar cell with the nanorod array structure is depicted in FIG. 1, and the process of manufacturing the same is similar to that depicted in FIG. 2A and FIG. 2B. Detailed descriptions are given below. The (100)-oriented p-type silicon wafer is immersed into a mixed solution of HF, H₂O, AgNO₃, and H₂O₂. Silver ions result in oxidization of silicon, so as to form silicon oxide. Silicon oxide then reacts with hydrofluoric acid to produce SiF₆²⁻. Through the continuous reactions, a nanorod array structure with the high aspect ratio is formed, wherein the depth is approximately 1 μm, and the width is approximately 100 nm. Since the as-prepared silicon wafers were wrapped with silver clusters after the chemical etching process, the wafers were rinsed into the silver etchant solution (NH₃OH:H₂O₂=3:1) to remove silver clusters away.

Thereafter, a phosphorous diffusion process is performed. A phosphorus-containing thin film is spin-coated onto the silicon wafer. A thermal treatment is performed at 900° C. for 30 minutes in a nitrogen atmosphere to diffuse the phosphorus. Thereby, the conductive type of the nanorod array and the conductive type of the silicon wafer below the nanorod array are changed to the n-type.

A thermal evaporator is then applied to deposit aluminum with the thickness of about 1.2 μm onto the back side of the silicon wafer, and the resultant aluminum (i.e., the first electrode 18 shown in FIG. 1) serves as a back electrode. An annealing process is performed on the back electrode. Through the annealing process performed on the back electrode, a p+ layer (not shown) can be formed on a portion of the silicon wafer adjacent to the back electrode. Since the concentration of the minority carriers (electrons) in the p+ layer is extremely low, the carrier recombination rate can be significantly lowered down, and the efficiency of the solar cell can be improved. In the reference example, the optimal annealing conditions include implementation of the annealing process at 600° C. for 25 minutes.

An evaporation process is performed to form silver with the thickness of about 2.5 μm on the front side of the silicon wafer, and the silver serves as the front electrode (e.g., the second electrode 20 depicted in FIG. 1). Due to the poor adhesion between silver and silicon, a nickel layer with the thickness of about 5 nm needs be coated as an adhesion layer prior to evaporation of silver.

The properties of the solar cell in the reference example, such as an open circuit voltage (V_{OC}), short circuit current density (J_{SC}), and photoelectric conversion efficiency, are listed in Table 1.

### Experimental Example 1

The structure of the solar cell described in the experimental example 1 is shown in FIG. 2C. The method of manufacturing the structure of the solar cell in the experimental example 1 is similar to that in the reference example, while the difference therebetween lies in that aluminum oxide with the thickness of about 5 nm is formed by performing an ALD process after the front electrode (i.e., the second electrode 106 shown in FIG. 2C) is formed, and the aluminum oxide serves as the passivation layer 108. In the experimental example 1, the ALD process is performed in a single-pulse mode. That is to say, the ALD cycle contains the following sequence: one TMA pulse→p inert gas purge→one H₂O vapor pulse→inert gas purge, for forming aluminum oxide.

In the experimental example 1, the system applied for measuring the characteristics of the solar cell is the same as that applied in the reference example. V_{OC}, J_{SC}, and photoelectric conversion efficiency of the solar cell described in the experimental example 1 are listed in Table 1.

### Experimental Example 2

The structure of the solar cell in the experimental example 2 is shown in FIG. 2C. The method of manufacturing the structure of the solar cell in the experimental example 2 is similar to that in the experimental example 1. Namely, aluminum oxide with the thickness of about 5 nm is formed by performing an ALD process, and the aluminum oxide serves as the passivation layer 108. The difference therebetween lies in that the ALD process is performed in a multi-pulse mode in the experimental example 2. That is to say, the ALD cycle contains the following sequence: two TMA pulses→inert gas purge→two H₂O vapor pulses→inert gas purge, for forming aluminum oxide.

In the experimental example 2, the system applied for measuring the characteristics of the solar cell is the same as that applied in the reference example. V_{OC}, J_{SC}, and photoelectric conversion efficiency of the solar cell described in the experimental example 2 are listed in Table 1.

### Experimental Example 3

The structure of the solar cell in the experimental example 3 is shown in FIG. 2C. The method of manufacturing the structure of the solar cell in the experimental example 3 is similar to that in the experimental example 2. Namely, the ALD process is performed in the multi-pulse mode to form aluminum oxide, and the aluminum oxide serves as the passivation layer 108. The difference therebetween lies in the thickness of the aluminum oxide (the passivation layer 108). Specifically, the thickness of the aluminum oxide (the passivation layer 108) is about 10 nm in the experimental example 3.

In the experimental example 3, the system applied for measuring the characteristics of the solar cell is the same as that applied in the reference example. V_{OC}, J_{SC}, and photoelectric conversion efficiency of the solar cell described in the experimental example 3 are listed in Table 1.

### Experimental Example 4

The structure of the solar cell in the experimental example 4 is shown in FIG. 2C. The method of manufacturing the structure of the solar cell in the experimental example 4 is similar to that in the experimental example 3. The difference therebetween lies in the thickness of the aluminum oxide (the passivation layer 108). Specifically, the thickness of the aluminum oxide (the passivation layer 108) is about 20 nm in the experimental example 4.

In the experimental example 4, the system applied for measuring the characteristics of the solar cell is the same as that applied in the reference example. V_{OC}, J_{SC}, and photoelectric conversion efficiency of the solar cell described in the experimental example 4 are listed in Table 1.

### Experimental Example 5

The structure of the solar cell in the experimental example 5 is shown in FIG. 2C. The method of manufacturing the structure of the solar cell in the experimental example 5 is similar to that in the experimental example 2. Namely, the ALD process is performed in the multi-pulse mode to form aluminum oxide with the thickness of about 5 nm, and the aluminum oxide serves as the passivation layer 108. However, after the passivation layer 108 is formed, an annealing process is performed on the aluminum oxide (the passivation layer 108) in the experimental example 5, and the annealing conditions include implementation of the annealing process at 400° C. for 30 minutes in a 100%-nitrogen atmosphere.

In the experimental example 5, the system applied for measuring the characteristics of the solar cell is the same as that applied in the reference example. V_{OC}, J_{SC}, and photoelectric conversion efficiency of the solar cell described in the experimental example 5 are listed in Table 1.

### Experimental Example 6

The structure of the solar cell in the experimental example 6 is shown in FIG. 2C. The method of manufacturing the structure of the solar cell in the experimental example 6 is similar to that in the experimental example 5. The difference therebetween lies in that the annealing conditions in the experimental example 6 include implementation of the annealing process at 400° C. for 30 minutes in an atmosphere of 5% hydrogen and 95% nitrogen.

In the experimental example 6, the system applied for measuring the characteristics of the solar cell is the same as that applied in the reference example. V_{OC}, J_{SC}, and photoelectric conversion efficiency of the solar cell described in the experimental example 6 are listed in Table 1.

### Experimental Example 7

The structure of the solar cell in the experimental example 7 is shown in FIG. 2C. The method of manufacturing the structure of the solar cell in the experimental example 7 is similar to that in the experimental example 2. Namely, the ALD process is performed in the multi-pulse mode to form the passivation layer 108 with the thickness of about 5 nm. The difference therebetween lies in a material of the passivation layer 108 is magnesium oxide in the experimental example 7.

In the experimental example 7, the system applied for measuring the characteristics of the solar cell is the same as that applied in the reference example. V_{OC}, J_{SC}, and photoelectric conversion efficiency of the solar cell described in the experimental example 7 are listed in Table 1.

### Experimental Example 8

The structure of the solar cell in the experimental example 8 is shown in FIG. 2C. The method of manufacturing the structure of the solar cell in the experimental example 8 is similar to that in the experimental example 2. Namely, the ALD process is performed in the multi-pulse mode to form the passivation layer 108 with the thickness of about 5 nm. The difference therebetween lies in a material of the passivation layer 108 is zirconium oxide in the experimental example 8.

In the experimental example 8, the system applied for measuring the characteristics of the solar cell is the same as that applied in the reference example. V_{OC}, J_{SC}, and photoelectric conversion efficiency of the solar cell described in the experimental example 8 are listed in Table 1.

### Experimental Example 9

The structure of the solar cell in the experimental example 9 is shown in FIG. 3B. The method of manufacturing the structure of the solar cell in the experimental example 9 is similar to that in the experimental example 6. The difference therebetween lies in that the ALD process is performed to form aluminum oxide with the thickness of about 5 nm (i.e., the film layer 108a with low interfacial state density) in the experimental example 9. An annealing process 109 is performed at 400° C. for 30 minutes in an atmosphere of 5% hydrogen and 95% nitrogen. Then an ALD process is performed to form zirconium oxide with the thickness of about 10 nm (i.e., the film layer 108b with high fixed charge density). According to the experimental example 9, aluminum oxide has low interfacial state density; hence, the carrier recombination rate through interfacial states may be suppressed. Further, zirconium oxide has high fixed charge density, thus repelling minority carriers (holes) in the n-type region away from the interface. This may further reduce the carrier recombination rate rate.

In the experimental example 9, the system applied for measuring the characteristics of the solar cell is the same as that applied in the reference example. V_{OC}, J_{SC}, and photoelectric conversion efficiency of the solar cell described in the experimental example 9 are listed in Table 1.

TABLE 1

| | | | Photoelectric |
|---|---|---|---|
| | | | Conversion Efficiency |
| | V_{OC} (V) | J_{SC} (mA/cm²) | (%) |
| Reference | 0.555 | 32.23 | 13.31 |
| Example | | | |
| Experimental | 0.550 | 34.84 | 14.39 |
| Example 1 | | | |
| Experimental | 0.550 | 36.44 | 15.05 |
| Example 2 | | | |
| Experimental | 0.560 | 35.88 | 14.94 |
| Example 3 | | | |
| Experimental | 0.555 | 36.55 | 15.11 |
| Example 4 | | | |
| Experimental | 0.555 | 36.55 | 15.46 |
| Example 5 | | | |
| Experimental | 0.565 | 38.44 | 16.53 |
| Example 6 | | | |
| Experimental | 0.55 | 36.21 | 15.21 |
| Example 7 | | | |
| Experimental | 0.555 | 35.53 | 14.59 |
| Example 8 | | | |
| Experimental | 0.570 | 32.23 | 17.24 |
| Example 9 | | | |

TABLE 2

| | Conditions of Preparing Passivation Layer | | | |
|---|---|---|---|---|
| | | Annealing | | |
| | Material | Atmosphere | Thickness | Pulse Mode |
| Experimental | Aluminum | n/a | 5 nm | 1 pulse |
| Example 1 | Oxide | | | |
| Experimental | Aluminum | n/a | 5 nm | 2 pulses |
| Example 2 | Oxide | | | |
| Experimental | Aluminum | n/a | 10 nm | 2 pulses |
| Example 3 | Oxide | | | |
| Experimental | Aluminum | n/a | 20 nm | 2 pulses |
| Example 4 | Oxide | | | |
| Experimental | Aluminum | 100% N₂ | 5 nm | 2 pulses |
| Example 5 | Oxide | | | |
| Experimental | Aluminum | 5% H₂ | 5 nm | 2 pulses |
| Example 6 | Oxide | 95% N₂ | | |
| Experimental | Magnesium | n/a | 5 nm | 2 pulses |
| Example 7 | Oxide | | | |
| Experimental | Zirconium | n/a | 5 nm | 2 pulses |
| Example 8 | Oxide | | | |
| Experimental | Aluminum | 5% H₂ | Aluminum | Aluminum |
| Example 9 | Oxide + | 95% N₂ | Oxide: 5 nm | Oxide: |
| | Zirconium | | Zirconium | 2 pulses |
| | Oxide | | Oxide: 10 nm | Zirconium |
| | | | | Oxide: |
| | | | | 2 pulses |

Conditions of preparing the passivation layer in each experimental example are summarized in Table 2. Please refer to both Table 1 and Table 2. Compared to the solar cell described in the reference example, the photoelectric conversion efficiency of solar cell in each experimental example, regardless of the material of the passivation layer, has been the significantly improved by 1.08%-3.93% after the passivation layer is formed. The ALD process is preferably performed in the double-pulse mode. After the passivation layer is formed by performing the ALD process, an annealing process may be performed to further improve the photoelectric conversion efficiency. In particular, if the film layer with low interfacial state density (the aluminum oxide layer in the experimental example 9) is formed by performing the ALD process, an annealing process is performed, and then the film layer with high fixed charge density (the zirconium oxide layer in the experimental example 9) is formed by performing the ALD process, the optimal photoelectric conversion efficiency may be achieved.

In the previous embodiments and experimental examples, the p-type silicon wafer is applied together with the n-type dopants (e.g., phosphorous), so as to form a p-n junction. Nevertheless, in other embodiments of the invention, the n-type silicon wafer along with the p-type dopants may also be utilized in the method of manufacturing the solar cell described herein. In this case, appropriate materials of the passivation layer (including a film layer with low interfacial state density and a film layer with high fixed charge density) need be properly determined, so as to ensure the effects of reducing the interfacial state density and repelling the minority carriers away from the interface.

In light of the foregoing, the method of manufacturing the solar cell is provided herein. According to the method, after the silicon wafer is etched to form the nanorod structure with the high aspect ratio, the ALD process is performed to form the passivation layer. ALD proceeds through chemical reactions only at the substrate surface, leading to the self-limiting mechanism and layer-by-layer growth. Due to the characteristics of the ALD process, the invention has at least the following advantages: (1) the atomic scale control of formation of the passivation layer is possible; (2) accurate control of thickness of the passivation layer is possible; (3) accurate control of composition of the passivation layer is possible; (4) High uniformity of the passivation layer can be achieved; (5) Excellent conformality and step coverage of the passivation layer can be accomplished; (6) there is no pinhole structure in the passivation layer, and the defect density of the passivation layer is low; (7) large-scale and batch production of the passivation layer is possible; and (8) the deposition temperature is low.

Accordingly, the surface defects of the nanorod structure can be significantly reduced, the carrier recombination through the interfacial states can be suppressed, and the photoelectric conversion efficiency of the solar cell can be improved by the surface passivation layer prepared by the ALD process.

The method of manufacturing the solar cell described herein further includes forming the passivation layer with a composite structure by performing the ALD process. The resultant passivation layer includes the film layer with low interfacial state density and the film layer with high fixed charge density. The film layer with low interfacial state density leads to reduction of carrier recombination through the interfacial states. In addition, the film layer with high fixed charge density is formed upon the film layer with the low interfacial state density, which keeps minority carriers away from the interface and further reduces the carrier recombination rate. As a result, the solar cell formed by performing the manufacturing method described herein has the improved photoelectric conversion efficiency in comparison with the conventional solar cell.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A method of manufacturing a solar cell, comprising:
providing a first-conductive-type silicon wafer, the silicon wafer having a first surface and a second surface facing each other, a plurality of nanorods being located on the first surface;
performing a doping process, such that the conductive type of the nanorods and the conductive type of one portion of the silicon wafer located below the nanorods are changed to a second conductive type;
forming a first electrode on the second surface;
performing a first annealing process on the first electrode;
forming a second electrode on a partial region of the first surface; and
performing an atomic layer deposition process to form a passivation layer on the first surface and surfaces of the nanorods.

2. The method of manufacturing the solar cell as recited in claim 1, wherein the passivation layer comprises a film layer with low interfacial state density and a film layer with high fixed charge density, and the film with high fixed charge density is formed upon the film layer with low interfacial state density.

3. The method of manufacturing the solar cell as recited in claim 2, wherein a method of forming the passivation layer comprises:
performing a first atomic layer deposition process to form the film layer with low interfacial state density on the first surface and the surfaces of the nanorods; and
performing a second atomic layer deposition process to form the film layer with high fixed charge density upon the film layer with low interfacial state density.

4. The method of manufacturing the solar cell as recited in claim 3, further comprising performing a second annealing process on the film layer with low interfacial state density after performing the first atomic layer deposition process and before the second atomic layer deposition process.

5. The method of manufacturing the solar cell as recited in claim 3, further comprising performing a second annealing process after performing the second atomic layer deposition process.

6. The method of manufacturing the solar cell as recited in claim 1, further comprising performing a second annealing process on the passivation layer after forming the passivation layer.

7. A solar cell, comprising:
a silicon wafer having a first surface and a second surface facing each other, a plurality of nanorods being located on the first surface, wherein the conductive type of the nanorods and the conductive type of one portion of the silicon wafer located below the nanorods are first conductive types, and the conductive type of the other portion of the silicon wafer is a second conductive type;
a first electrode configured on the second surface;
a second electrode configured on a partial region of the first surface; and
a passivation layer configured on the first surface and surfaces of the nanorods.

8. The solar cell as recited in claim 7, wherein a material of the passivation layer comprises Al₂O₃, AlN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}ByO_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof.

9. The solar cell as recited in claim 7, wherein the passivation layer comprises a film layer with low interfacial state density and a film layer with high fixed charge density, and the film with high fixed charge density is configured upon the film layer with low interfacial state density.

10. The solar cell as recited in claim 9, wherein a material of the film layer with low interfacial state density comprises Al₂O₃, AN, AlP, AlAs, Al_{X}TiyO_{Z}, Al_{X}CryO_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}ZryO_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, HO₂O₃, Er₂O₃, Tm₂O₃, Lu₂O₃, or a combination thereof.

11. The solar cell as recited in claim 9, wherein a material of the film layer with high fixed charge density comprises Al₂O₃, AN, AlP, AlAs, Al_{X}Ti_{Y}O_{Z}, Al_{X}Cr_{Y}O_{Z}, Al_{X}Zr_{Y}O_{Z}, Al_{X}Hf_{Y}O_{Z}, Al_{X}Si_{Y}O_{Z}, B₂O₃, BN, B_{X}P_{Y}O_{Z}, BiO_{X}, Bi_{X}Ti_{Y}O_{Z}, BaS, BaTiO₃, CdS, CdSe, CdTe, CaO, CaS, CaF₂, CuGaS₂, CoO, CoO_{X}, Co₃O₄, CrO_{X}, CeO₂, Cu₂O, CuO, Cu_{X}S, FeO, FeO_{X}, GaN, GaAs, GaP, Ga₂O₃, GeO₂, HfO₂, Hf₃N₄, HgTe, InP, InAs, In₂O₃, In₂S₃, InN, InSb, LaAlO₃, La₂S₃, La₂O₂S, La₂O₃, La₂CoO₃, La₂NiO₃, La₂MnO₃, MoN, Mo₂N, Mo_{X}N, MoO₂, MgO, MnO_{X}, MnS, NiO, NbN, Nb₂O₅, PbS, PtO₂, Po_{X}, P_{X}B_{Y}O_{Z}, RuO, Sc₂O₃, Si₃N₄, SiO₂, SiC, Si_{X}Ti_{Y}O_{Z}, Si_{X}Zr_{Y}O_{Z}, Si_{X}Hf_{Y}O_{Z}, SnO₂, Sb₂O₅, SrO, SrCO₃, SrTiO₃, SrS, SrS_{1-X}Se_{X}, SrF₂, Ta₂O₅, TaO_{X}N_{Y}, Ta₃N₅, TaN, TaN_{X}, Ti_{X}Zr_{Y}O_{Z}, TiO₂, TiN, Ti_{X}Si_{Y}N_{Z}, Ti_{X}Hf_{Y}O_{Z}, VO_{X}, WO₃, W₂N, W_{X}N, WS₂, W_{X}C, Y₂O₃, Y₂O₂S, ZnS_{1-X}Se_{X}, ZnO, ZnS, ZnSe, ZnTe, ZnF₂, ZrO₂, Zr₃N₄, PrO_{X}, Nd₂O₃, Sm₂O₃, Eu₂O₃, Gd₂O₃, Dy₂O₃, Ho₂O₃, Er₂O₃, Tm₂O₃, Lu₂O₃, or a combination thereof.

12. The solar cell as recited in claim 7, wherein a thickness of the passivation layer ranges from about 1 Å to about 1 μm.
